(19) United States
(12) Patent Application Publication
(10) Pub. No.: US 2011/0296286 A1
(43) Pub. Date: Dec. 1, 2011

(54) INTERFACE DEVICE, DECODED DATA VALIDITY DETERMINATION METHOD AND RECORDING DEVICE

(75) Inventors: Masashi Sakamoto, Ome-shi (JP); Shuichi Ishii, Ome-shi (JP)

(73) Assignee: Kabushiki Kaisha Toshiba, Tokyo (JP)

(21) Appl. No.: 13/039,791

(22) Filed: Mar. 3, 2011

(30) Foreign Application Priority Data
May 28, 2010 (JP) 2010-123554

(51) Int. Cl. H03M 13/09; G06F 11/10

(52) U.S. Cl. 714/807; 714/E11.032

(57) ABSTRACT

According to one embodiment, an interface device including a decoding module configured to decode received data, a storage module configured to store data obtained after the decoding module performs decoding, a CRC module configured to detect a CRC error included in the data obtained after the decoding module performs the decoding, an error detection module configured to detect a decoding error included in the data obtained after the decoding module performs the decoding, and a data processing module configured to process, as valid data, the data that is obtained after the decoding module performs the decoding and stored in the storage module when the decoding error detected by the error detection module is non-user data and the CRC module does not detect any CRC error.

### CROSS-REFERENCE TO RELATED APPLICATIONS

This application is based upon and claims the benefit of priority from Japanese Patent Application No. 2010-123554, filed May 28, 2010; the entire contents of which are incorporated herein by reference.

### FIELD

Embodiments described herein relate generally to an interface device, a decoded data validity determination method and a recording device.

### BACKGROUND

A Serial ATA interface (interface based on the Serial Advanced Technology (AT) Attachment standards) has been used as an interface that connects a host system such as a personal computer (PC) to a device typified by a hard disk drive (HDD, it may be simply referred to as disk drive).

In a Serial ATA interface (hereinafter, simply referred to as SATA), the management of control information and data that is exchanged between the host system and the device is conducted by use of packets (or frames called “frame information structure” [FIS]).

A cyclic redundancy check (CRC) that is utilized to check errors is attached to a packet (or FIS).

When a CRC is attached to data such as a packet (or FIS), the packet (or FIS) is determined as invalid if an error is included in the CRC at the CRC-checking of decoded data.

### BRIEF DESCRIPTION OF THE DRAWINGS

A general architecture that implements the various feature of the embodiments will now be described with reference to the drawings. The drawings and the associated descriptions are provided to illustrate the embodiments and not to limit the scope of the invention.

FIG. 1 is an exemplary diagram showing an example of the system structure according to an embodiment;

FIG. 2 is an exemplary diagram showing an example of the interface structure according to an embodiment;

FIG. 3 is an exemplary diagram showing an example of a decoded data validity determination method according to an embodiment; and

FIG. 4 is an exemplary diagram showing an example of a recording device according to an embodiment.

### DETAILED DESCRIPTION

Various embodiments will be described hereinafter with reference to the accompanying drawings. In general, according to one embodiment, an interface device comprising: a decoding module configured to decode received data; a storage module configured to store data obtained after the decoding module performs decoding; a CRC module configured to detect a CRC error included in the data obtained after the decoding module performs the decoding; an error detection module configured to detect a decoding error included in the data obtained after the decoding module performs the decoding; and a data processing module configured to process, as valid data, the data that is obtained after the decoding module performs the decoding and stored in the storage module when the decoding error detected by the error detection module is non-user data and the CRC module does not detect any CRC error.

Embodiments will now be described hereinafter in detail with reference to the accompanying drawings.

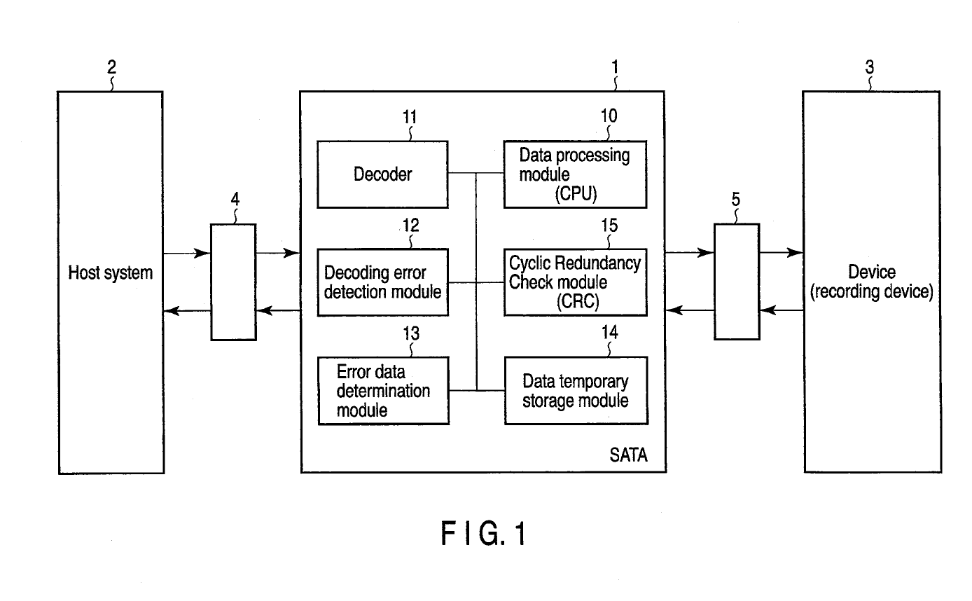

FIG. 1 shows an example of a system structure comprising an interface device according to the present embodiment.

The system of the present embodiment comprises a host system 2 and a device (recording device) 3 that are connected to each other by means of a Serial ATA interface (hereinafter, referred to as SATA) 1.

The host system 2 includes a personal computer (PC), for example. The host system 2 may be a mobile terminal to be connected to a network or a cellular phone device to be carried out communications.

The recording device 3 for example a hard disk drive (HDD), and includes a disk medium (recording medium) and a head to write information to the disk medium and to read information from the disk medium, and performs data recording and reproducing onto the disk medium. The recording device 3 may be a solid state drive (SSD), or an optical disk drive that can write information to and read information from, for example, a Digital Versatile Disk (DVD) standard optical disk or a Compact Disk (CD) standard optical disk. Furthermore, the recording device 3 may be integrated into the host system 2, or may be detachably arranged in the host system 2.

The SATA 1 comprises at least a data processing module (microprocessor such as a CPU) 10 configured to process the data exchanged with the recording device 3 and control the operations of the later-described components, a decoder 11 configured to receive and decode the data input from the host system 2 such as a packet (or a frame called a frame information structure [FIS]), a decoding error detection module 12 configured to detect a decoding error in the data decoded by the decoder 11 such as user data, an error data determination module 13 configured to determine whether or not the data having a decoding error detected by the decoding error detection module 12 is user data, a data temporary storage module 14 configured to store the data decoded by the decoder 11, and a CRC module 15 configured to check a cyclic redundancy check (CRC) that is attached to a packet (or FIS) to be used for checking errors in the packet. For the data temporary storage module 14, part of a buffer memory that is generally used as a buffer for packets may be adopted, although it is not shown in the drawings. Moreover, it is preferable that the host system 2 and the decoder 11 be connected to each other by a transmission/reception unit that is not shown in the drawings and is configured to control packet transmission/reception (input/output) or by a bus 4. In addition, it is preferable that the CRC module 15 and the recording device 3 be connected to each other by a transmission/reception unit that is not shown in the drawings and is configured to control the packet transmission/reception (input/output) or by a bus 5.

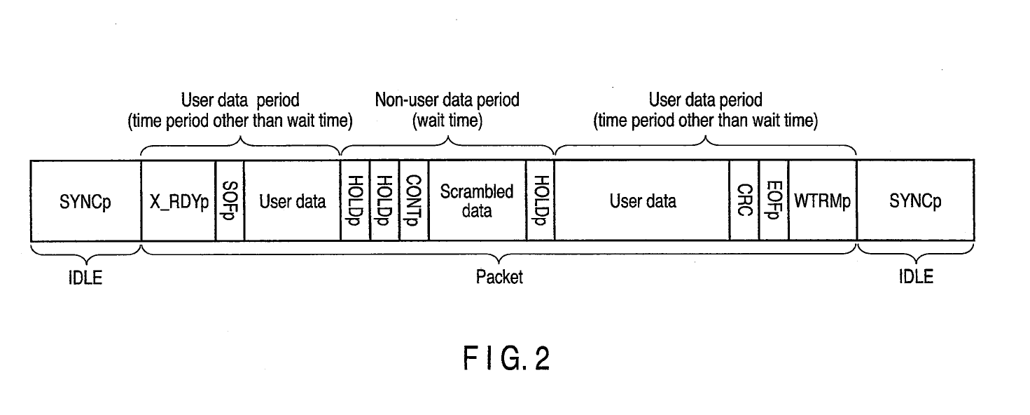

FIG. 2 shows an example structure of a packet that is input from the host system to the SATA.

A packet supplied from the host system 2 to the SATA 1 includes between “IDLE” and “IDLE” in sequence “TAG/address section (not-discussed)”, “X_RDY”, “SOF (Start Of Frame, which is a packet start signal)”, “(leading side) User data”, at least one of “HOLD”, “Scrambled data”, “HOLD”, “(trailing side) User data”, “CRC”, “EOF (End Of Frame, which is a packet end signal)” and “WTRM”. The “IDLE” indicates an interval the non-transmission/reception time. The “(leading side) User data” positioned following the “X_RDY” and the “SOF” in User data period (time period other than wait time). The “Scrambled data” positioned following the at least one of the “HOLD (CONT)” in Non-user data period (wait time). The “(trailing side) User data” positioned in advance of the “CRC”, the “EOF” and the “WTRM” in User data period (time period other than wait time). Therefore, the “IDLE”, the “(leading side) User data”, the “Scrambled data” and the “(trailing side) User data” are arranged in order.

The time period between “HOLD” and “HOLD” is referred to as, for example, “wait time”, and is attached when, for example, the timing needs to be adjusted (to ensure synchronization) in transmission and reception of packets between the host system 2 and the SATA 1. Thus, even when the data in the time period called “wait time” includes an error in decoding performed by the decoder 11, it would not influence the user data. The data in the time period called “wait time” can be easily distinguished from the user data by commands such as “HOLD”, “HOLDA”, “CONT”, “scrambled data” and “ALIGN”.

This means that the user data remains unaffected even when the data in the time period of “wait time” includes an error in the decoding performed by the decoder 11. Thus, even if the aforementioned data in the time period of “wait time” that has a decoding error made by the decoder 11, the user data included in this packet should be considered valid.

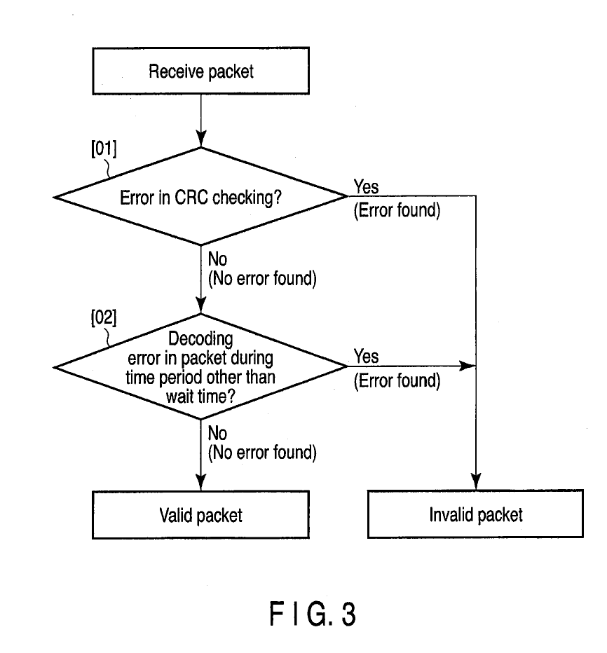

FIG. 3 shows an example method of determining that the user data included in a packet is valid even if the data in the aforementioned time period of “wait time” includes a decoding error made by the decoder.

As shown in FIG. 3, after a packet received by means of the transmission/reception unit or the bus 4 is decoded by the decoder 11, the CRC module 15 checks to determine whether or not the “CRC” of the packet indicates an error [01]. Here, when the “CRC” of the packet includes an error [01-YES], the data processing module 10 determines that the packet is invalid (invalid packet). Thus, a request of resending the packet is returned to the host system 2 by means of the data processing module 10.

At [01], if there is no error in the “CRC” of the packet [01-N0], the error data determination module 13 checks to determine whether or not there is any decoding error in the packet during the aforementioned “wait time”, or in other words, whether or not a decoding error detected by the decoding error detection module 12, if any, is located in any time period other than the “wait time” [02]. More specifically, when the decoding error detection module 12 detects a decoding error, if the error is found to be located within a time period other than the “wait time” as a result of checking the position of the error at the error data determination module 13 [02-YES], the data processing module 10 determines that the packet is invalid (invalid packet). Then, a request for resending the packet is returned to the host system 2 by means of the data processing module 10.

At [02], when the decoding error detection module 12 detects a decoding error in the packet and this error is not located within a time period other than “wait time”, or in other words, when the error is found to be located within the “wait time”, as a result of checking the position of the decoding error at the error data determination module 13 [02-N0], the data processing module 10 determines that the packet is valid (valid packet). Thus, for example, the packet that is temporarily stored in the data temporary storage module 14 is supplied as a valid packet to the downstream recording device (device) 3 by means of the transmission/reception unit or the bus 5, under the control of the data processing module 10. This means that a request for resending the packet does not have to be issued.

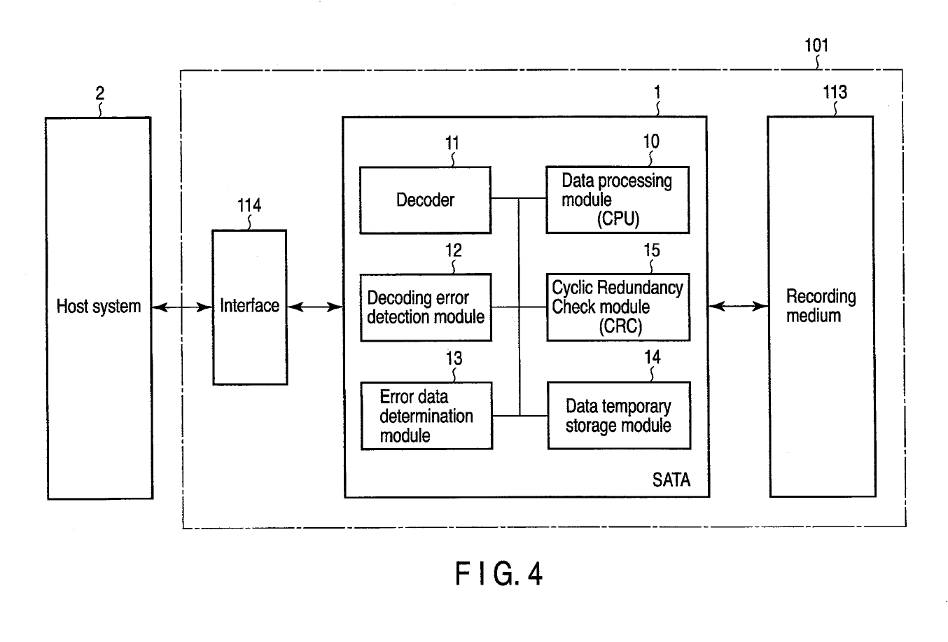

FIG. 4 shows an embodiment of the recording device.

For example, a recording device 101 may be given a structure in which the Serial ATA interface (SATA) 1 and a recording medium 113 are connected to each other by a signal line, and the SATA 1 and the host system 2 are connected to each other by means of an interface 114.

Furthermore, the recording medium 113 may be a hard disk drive unit (HDD), a solid-state drive (SDD), or an optical disk drive device that can write information to a Digital Versatile Disk (DVD) standard optical disk or a Compact Disk (CD) standard optical disk and read information from such an optical disk.

As discussed above, even when the data of a decoded packet includes a decoding error, if the data having the decoding error is non-user data (data within the “wait time”), the user data of the packet can be used by processing the packet as it is as a valid packet, under the condition that no error is included in the CRC checking.

More specifically, when the data having a decoding error does not include any user data, a packet in which no error is detected at the CRC checking is processed as valid packet so that a packet resending process (i.e., issuing a resending request to the host system, re-receiving and decoding the packet, and checking its CRC) does not need to be conducted. For this reason, the time required to normally receive the target packet can be shortened.

Moreover, because a decoding error caused during the “wait time (non-user data)” is not regarded as an error (i.e., the error does not render the packet invalid), the number of packet transmission errors can be reduced. Thus, the quality of data transmitted and received by use of the SATA can be improved.

Needless to say, the validation of the decoded data in the packet transmission and reception is applicable to the data transmitted from the device to the host system.

As explained above, according to the present embodiments, the number of packets that need to be subjected to the resending process because of a decoding error can be reduced, and thus the time required for the transmission and reception of the target packet can be reduced. This speeds up the transmission and reception of any number of packets.

Moreover, because the number of packets to be transmitted and received can be reduced, the possibility of failures in the hardware (disk drive or device) (i.e., the probability of occurrence of failures) can be reduced. Hence, the lifespan of the hardware (device) can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An interface device comprising:
a decoding module configured to decode received data;
a storage module configured to store data obtained after the decoding module performs decoding;
a CRC module configured to detect a CRC error included in the data obtained after the decoding module performs the decoding;
an error detection module configured to detect a decoding error included in the data obtained after the decoding module performs the decoding; and
a data processing module configured to process, as valid data, the data that is obtained after the decoding module performs the decoding and stored in the storage module when the decoding error detected by the error detection module is non-user data and the CRC module does not detect any CRC error.

2. The device of claim 1, wherein the error detection module detects that the data in which the decoding error is non-user data.

3. A method for determination of validity in decoded data comprising:
storing decoded data obtained after decoding;
detecting a CRC error in the decoded data;
detecting a decoding error in the decoded data; and
determining that the decoded data that is stored is valid when no CRC error is detected and the decoding error is non-user data.

4. A recording apparatus comprising:
a decoding module configured to decode received data;
a storage module configured to store data obtained after the decoding module performs decoding;
a CRC module configured to detect a CRC error included in the data obtained after the decoding module performs the decoding;
an error detection module configured to detect a decoding error in the data obtained after the decoding module performs the decoding;
a data processing module configured to process, as valid data, the data that is obtained after the decoding and stored in the storage module when the decoding error detected by the error detection module is non-user data and the CRC module does not detect any CRC error; and
a record module configured to record the valid data supplied by the data processing module.

5. The apparatus of claim 4, wherein the error detection module detects that the decoded data in which the decoding error is non-user data.
